(19) United States
(12) Patent Application Publication
(10) Pub. No.: US 2004/0202332 A1
(43) Pub. Date: Oct. 14, 2004

(54) Sound-field setting system

(76) Inventors: Yoshihisa Murohashi, Maebashi-shi (JP); Toshitaka Abe, Maebashi-shi (JP); Hiroshi Kodama, Sagamihara-shi (JP); Toshimitsu Uchiyama, Maebashi-shi (JP)

Correspondence Address: LOUIS WOO, LAW OFFICE OF LOUIS WOO, 717 NORTH FAYETTE STREET, ALEXANDRIA, VA, 22314, US

(21) Appl. No.: 10/799,773

(22) Filed: Mar. 15, 2004

(30) Foreign Application Priority Data
Mar. 20, 2003 (JP) 2003-077285

(51) Int. Cl. H04R 5/00; H03G 3/00

(52) U.S. Cl. 381/17; 381/104

(57) ABSTRACT

Loudspeakers of plural channels are used as microphones to convert a test sound generated at a listening point into corresponding electric signals respectively. Moments of arrival of the test sound at the loudspeakers are detected in response to the electric signals respectively. Desired delay times for audio signals of the plural channels are calculated from the detected moments of arrival of the test sound at the loudspeakers. Volume levels of the electric signals are detected. Desired volume levels for the audio signals are calculated from the detected volume levels. The audio signals are delayed by the desired delay times respectively and volume levels of the audio signals are controlled at the desired volume levels respectively to get processing-resultant audio signals of the plural channels. The processing-resultant audio signals are fed to the loudspeakers respectively.

### BACKGROUND OF THE INVENTION

1. Field of the Invention

This invention generally relates to a sound-field setting system. This invention particularly relates to a method of setting a sound field in an audio reproducing system including loudspeakers of different channels. In addition, this invention particularly relates to a computer program for setting a sound field. Furthermore, this invention particularly relates to an audio reproducing apparatus having the function of setting a sound field.

2. Description of the Related Art

Typical audio signals recorded on DVDs (digital versatile discs) originate from multi-channel sound sources. A conventional system for reproducing a multi-channel sound source has a plurality of loudspeakers assigned to different channels respectively. In such multi-channel audio reproducing systems, there are known methods of optimally setting the sound field formed by loudspeakers. As will be mentioned later, the known methods have some problems.

### SUMMARY OF THE INVENTION

A general object of this invention is to solve the problems in the known methods.

It is a first specific object of this invention to provide an improved sound-field setting system.

It is a second specific object of this invention to provide an improved method of setting a sound field in an audio reproducing system.

It is a third specific object of this invention to provide an improved computer program for setting a sound field in an audio reproducing system.

It is a fourth specific object of this invention to provide an improved audio reproducing apparatus having the function of setting a sound field.

A first aspect of this invention provides a method of setting a sound field generated when audio signals of plural channels which are outputted from an audio signal reproducing apparatus are reproduced from loudspeakers of the respective channels. The method comprises the steps of cutting off the feed of the audio signals from the audio signal reproducing apparatus to the loudspeakers of the respective channels; capturing a test sound generated by a listener at a listening point by the loudspeakers of the respective channels as sound pickup data; detecting and comparing volume levels at predetermined points of the sound pickup data captured by the loudspeakers of the respective channels, and thereby generating volume adjusting data of the audio signals of the respective channels; and controlling volumes of the audio signals of the respective channels in response to the volume adjusting data respectively.

A second aspect of this invention is based on the first aspect thereof, and provides a method of setting a sound field which further comprises the steps of detecting and comparing timings of the data values at the predetermined points of the sound pickup data captured by the loudspeakers of the respective channels, and thereby generating delay time setting data of the audio signals of the respective channels; and controlling delay times of the audio signals of the respective channels in response to the delay time setting data respectively.

A third aspect of this invention is based on the first aspect thereof, and provides a method of setting a sound field wherein the predetermined points are points of timings at which exceeding a prescribed threshold occurs.

A fourth aspect of this invention is based on the second aspect thereof, and provides a method of setting a sound field wherein the predetermined points are points of timings at which exceeding a prescribed threshold occurs.

A fifth aspect of this invention provides a computer program for setting a sound field generated when audio signals of plural channels which are outputted from an audio signal reproducing apparatus are reproduced from loudspeakers of the respective channels. The computer program comprises the steps of cutting off the feed of the audio signals from the audio signal reproducing apparatus to the loudspeakers of the respective channels; capturing a test sound generated by a listener at a listening point by the loudspeakers of the respective channels as sound pickup data; detecting and comparing volume levels at predetermined points of the sound pickup data captured by the loudspeakers of the respective channels, and thereby generating volume adjusting data of the audio signals of the respective channels; and controlling volumes of the audio signals of the respective channels in response to the volume adjusting data respectively.

A sixth aspect of this invention is based on the fifth aspect thereof, and provides a computer program for setting a sound field which further comprises the steps of detecting and comparing timings of the data values at the predetermined points of the sound pickup data captured by the loudspeakers of the respective channels, and thereby generating delay time setting data of the audio signals of the respective channels; and controlling delay times of the audio signals of the respective channels in response to the delay time setting data respectively.

A seventh aspect of this invention is based on the fifth aspect thereof, and provides a computer program for setting a sound field wherein the predetermined points are points of timings at which exceeding a prescribed threshold occurs.

An eighth aspect of this invention is based on the sixth aspect thereof, and provides a computer program for setting a sound field wherein the predetermined points are points of timings at which exceeding a prescribed threshold occurs.

A ninth aspect of this invention provides an audio reproducing apparatus provided with a system for setting a sound field generated when audio signals of plural channels which are outputted from the audio reproducing apparatus are reproduced from loudspeakers of the respective channels. The audio reproducing apparatus comprises means for cutting off the feed of the audio signals from the audio signal reproducing apparatus to the loudspeakers of the respective channels; means for capturing a test sound generated by a listener at a listening point by the loudspeakers of the respective channels as sound pickup data; a detector for detecting volume levels at predetermined points of the sound pickup data captured by the loudspeakers of the respective channels; a generator for comparing the detected volume levels, and thereby generating volume adjusting data of the audio signals of the respective channels; and a controller for controlling volumes of the audio signals of the respective channels in response to the volume adjusting data respectively.

A tenth aspect of this invention is based on the ninth aspect thereof, and provides an audio reproducing apparatus further comprising a detector for detecting timings of the data values at the predetermined points of the sound pickup data captured by the loudspeakers of the respective channels; a generator for comparing the detected timings of the data values, and thereby generating delay time setting data of the audio signals of the respective channels; and a controller for controlling delay times of the audio signals of the respective channels in response to the delay time setting data respectively.

An eleventh aspect of this invention is based on the ninth aspect thereof, and provides an audio reproducing apparatus wherein the predetermined points are points of timings at which exceeding a prescribed threshold occurs.

A twelfth aspect of this invention is based on the tenth aspect thereof, and provides an audio reproducing apparatus wherein the predetermined points are points of timings at which exceeding a prescribed threshold occurs.

A thirteenth aspect of this invention provides a sound-field setting system comprising loudspeakers of plural channels; means for cutting off the feed of the audio signals from the audio signal reproducing apparatus to the loudspeakers of the respective channels; means for capturing a test sound generated by a listener at a listening point by the loudspeakers of the respective channels as sound pickup data; a detector for detecting volume levels at predetermined points of the sound pickup data captured by the loudspeakers of the respective channels; a generator for comparing the detected volume levels, and thereby generating volume adjusting data of the audio signals of the respective channels; and a controller for controlling volumes of the audio signals of the respective channels in response to the volume adjusting data respectively.

A fourteenth aspect of this invention is based on the thirteenth aspect thereof, and provides a sound-field setting system further comprising a detector for detecting timings of the data values at the predetermined points of the sound pickup data captured by the loudspeakers of the respective channels; a generator for comparing the detected timings of the data values, and thereby generating delay time setting data of the audio signals of the respective channels; and a controller for controlling delay times of the audio signals of the respective channels in response to the delay time setting data respectively.

A fifteenth aspect of this invention is based on the thirteenth aspect thereof, and provides a sound-field setting system wherein the predetermined points are points of timings at which exceeding a prescribed threshold occurs.

A sixteenth aspect of this invention is based on the fourteenth aspect thereof, and provides a sound-field setting system wherein the predetermined points are points of timings at which exceeding a prescribed threshold occurs.

A seventeenth aspect of this invention provides a sound-field setting system comprising loudspeakers of plural channels; first means for using the loudspeakers as microphones to convert a test sound generated at a desired listening point into corresponding electric signals respectively; second means for detecting amplitudes of the electric signals generated by the loudspeakers; third means for setting desired gains for input audio signals of the plural channels in response to the amplitudes detected by the second means; fourth means for amplifying the input audio signals at the desired gains set by the third means to generate amplified audio signals respectively; and fifth means for feeding the amplified audio signals generated by the fourth means to the loudspeakers respectively.

An eighteenth aspect of this invention provides a sound-field setting system comprising loudspeakers of plural channels; first means for using the loudspeakers as microphones to convert a test sound generated at a desired listening point into corresponding electric signals respectively; second means for detecting moments of arrival of the test sound at the loudspeakers in response to the electric signals generated by the loudspeakers respectively; third means for delaying input audio signals by delay times depending on the moments detected by the second means to generate delayed audio signals respectively; and fourth means for feeding the delayed audio signals to the loudspeakers respectively.

A nineteenth aspect of this invention provides a sound-field setting system comprising loudspeakers of plural channels; first means for using the loudspeakers as microphones to convert a test sound generated at a desired listening point into corresponding electric signals respectively; second means for detecting moments of arrival of the test sound at the loudspeakers in response to the electric signals generated by the loudspeakers respectively; third means for setting desired delay times for input audio signals of the plural channels in response to the moments detected by the second means; fourth means for delaying the input audio signals by the desired delay times set by the third means to generate delayed audio signals respectively; and fifth means for feeding the delayed audio signals to the loudspeakers respectively.

A twentieth aspect of this invention is based on the nineteenth aspect thereof, and provides a sound-field setting system further comprising sixth means for detecting amplitudes of the electric signals generated by the loudspeakers; seventh means for setting desired gains for the input audio signals in response to the amplitudes detected by the sixth means; eighth means for amplifying the input audio signals at the desired gains set by the seventh means to generate amplified audio signals respectively; and ninth means for feeding the amplified audio signals generated by the eighth means to the loudspeakers respectively.

### BRIEF DESCRIPTION OF THE DRAWINGS

FIG. 1 is a diagram of loudspeakers, a listener, and a listening point regarding a known method of setting a sound field.

FIG. 2 is a block diagram of a known audio reproducing apparatus.

FIG. 3 is a block diagram of a prior-art audio reproducing system.

FIG. 4 is a block diagram of an audio reproducing system according to a first embodiment of this invention.

FIG. 5 is a diagram of loudspeakers, a listener, and a desired listening point in the system of FIG. 4.

FIGS. 6A and 6B are a flowchart of a sound-field setting program for controlling a CPU in FIG. 4.

FIG. 7 is a diagram of loudspeakers of left and right channels, and a desired listening point in a first positional condition.

FIG. 8 is a time-domain diagram of the waveforms of electric signals which were generated by the loudspeakers in FIG. 7.

FIG. 9 is a diagram of the loudspeakers of the left and right channels, and the desired listening point in a second positional condition.

FIG. 10 is a time-domain diagram of the waveforms of electric signals which were generated by the loudspeakers in FIG. 9.

FIG. 11 is a diagram of the loudspeakers of the left and right channels, and the desired listening point in a third positional condition.

FIG. 12 is a time-domain diagram of the waveforms of electric signals which were generated by the loudspeakers in FIG. 11.

FIG. 13 is a flowchart of a sound-field setting program in a second embodiment of this invention.

### DETAILED DESCRIPTION OF THE INVENTION

Known methods of optimally setting a sound field in a multi-channel audio reproducing system will be explained below for a better understanding of this invention.

A first known method is on a fully manual basis. According to the first known method, a listener is required to actuate an operation unit or an input unit of the audio reproducing system and thereby manually implement a sequence of steps of loading the system with information about loudspeakers as follows:

1) setting a subwoofer; choice: present/absent;

2) setting a front loudspeaker; choice: large/small;

3) setting a center loudspeaker; choice: large/small/absent;

4) setting a rear loudspeaker; choice: large/small/absent;

5) setting a crossover frequency; choice: 80/100/120/150/200 Hz;

6) setting a distance from the listener to the front loudspeaker; choice: 0.3 m to 9.0 m;

7) setting a distance from the listener to the center loudspeaker; choice: 0.3 m to 9.0 m;

8) setting a distance from the listener to the rear loudspeaker; choice; 0.3 m to 9.0 m;

9) outputting a test tone via the loudspeakers;

10) center level adjustment; choice: −10 dB to +10 dB;

11) rear left-channel level adjustment; choice: −10 dB to 30 10 dB; and

12) rear right-channel level adjustment; choice: −10 to +10 dB.

A sound field optimal for the listener can be generated by the loudspeakers provided that the distances from the listener to the loudspeakers are properly set and are accurately notified to the system as setting information, that the center level, the rear left-channel level, and the rear right-channel level are properly set, and that the listener is in a correct position. The first known method requires the listener to carry out the foregoing 12 steps. Generally, carrying out the 12 steps is troublesome and takes a long time.

A second known method is implemented by the use of a microcomputer in the audio reproducing system. It is usual that the distances from the listener to the loudspeakers increase as the size of a room where the audio reproducing system is located increases. Accordingly, the configuration or placement of the loudspeakers tends to depend on the size of the room. A memory within the microcomputer is previously loaded with information representing typical configurations (or placements) of the loudspeakers. Furthermore, the memory is previously loaded with information about signal processing conditions for setting an optimal sound field in accordance with each typical configuration of the loudspeakers. According to the second known method, the listener is required to select one from the typical configurations of the loudspeakers, and to notify the audio reproducing system of the selected configuration. The microcomputer in the audio reproducing system provides the signal processing conditions corresponding to the selected configuration so that the optimal sound field can be automatically generated by the loudspeakers. In the case where the loudspeakers are in a configuration considerably different from the typical ones, it is difficult to generate an optimal sound field.

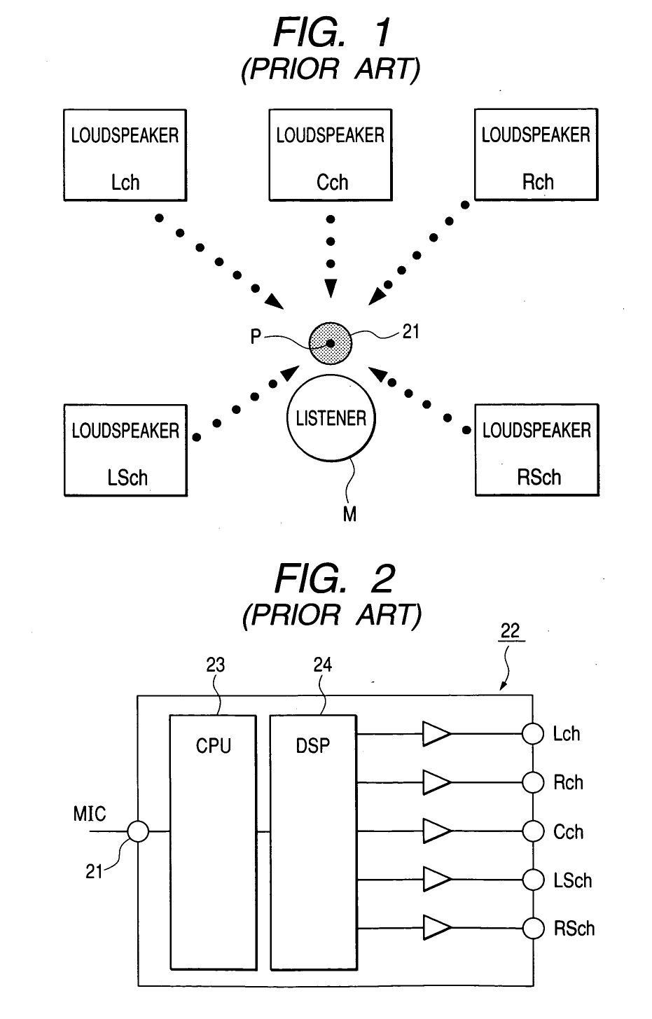

A third known method will be explained below with reference to FIGS. 1 and 2. The audio reproducing system has loudspeakers of different channels which include a left channel Lch, a center channel Cch, a right channel Rch, a left surround channel LSch, and a right surround channel RSch. The loudspeakers of the channels Lch, Rch, Cch, LSch, and RSch are arranged as shown in FIG. 1. The audio reproducing system also has a main apparatus 22 referred to as an audio reproducing apparatus 22. As shown in FIG. 2, the audio reproducing apparatus 22 has a combination of a central processing unit (CPU) 23 and a digital signal processor (DSP) 24. The DSP 24 is connected to the loudspeakers via respective amplifiers. Each of the amplifiers has an adjustable gain. The DSP 24 gives adjustable signal delay times to audio signals fed to the loudspeakers via the amplifiers. The amplifiers drive the loudspeakers during a normal reproducing mode of operation of the audio reproducing system.

According to the third known method, a listener M places a microphone 21 at a listening point P during a sound-field setting mode of operation of the audio reproducing system. The microphone 21 is connected with the CPU 23. The combination of the CPU 23 and the DSP 24 sequentially transmits tone signals to the loudspeakers of the channels Lch, Rch, Cch, LSch, and RSch via the amplifiers. At this time, the gain of each of the amplifiers and the signal delay times given by the DSP 24 are equal to initial values. The loudspeakers convert the tone signals into corresponding sounds. Portions of the sounds propagate from the loudspeakers to the microphone 21. The microphone 21 converts the applied sounds into corresponding electric signals referred to as detected tone signals.

During the sound-field setting mode of operation, the CPU 23 receives the detected tone signals from the microphone 21. The CPU 23 decides whether each of the detected tone signals is present or absent, and measures the delay of each of the detected tone signals from the corresponding transmitted tone signal. The CPU 23 analyzes the frequency conditions of each of the detected tone signals, and measures the amplitudes of each of the detected tone signals. The CPU 23 sets the gains of the amplifiers and the signal delay times given by the DSP 24 in response to the results of the forgoing decision, measurements, and analyzation so that an optimal sound field can be generated by the loudspeakers of the channels Lch, Rch, Cch, LSch, and RSch during the normal reproducing mode of operation of the audio reproducing system.

The microphone 21 increases the cost of the audio reproducing system. It is necessary for the listener M to place the microphone 21 at the listening point P.

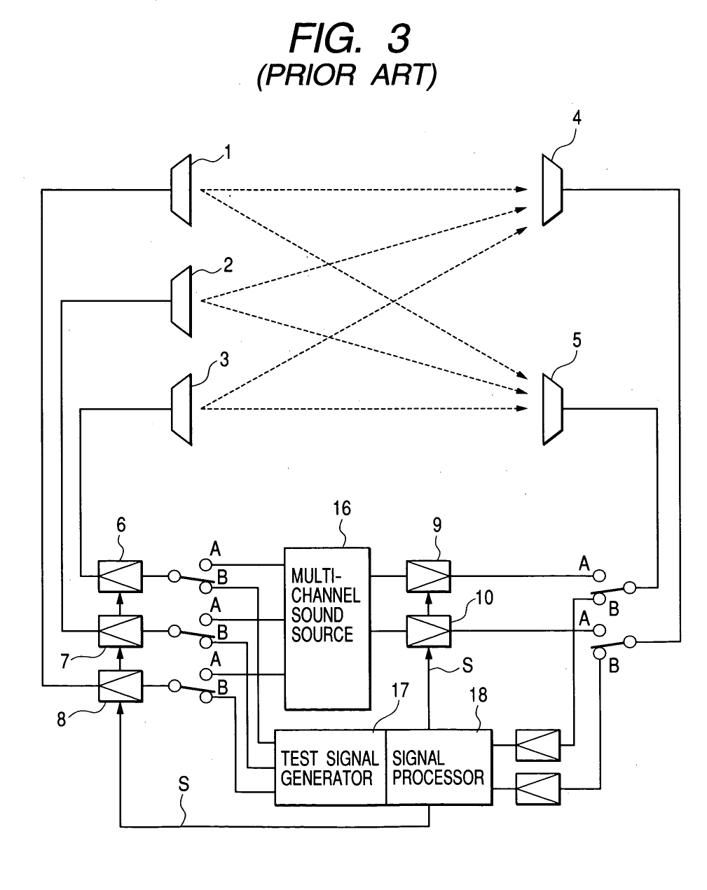

Japanese patent application publication number 6-38300/1994 discloses an audio reproducing system which implements a fourth known method. As shown in FIG. 3, the system of Japanese application 6-38300/1994 includes respective loudspeakers 1-5 of five channels, respective amplifiers 6-10 of the five channels, a multi-channel sound source 16, a signal generator 17, and a signal processor 18.

The fourth known method is carried out as follows. During an adjustment mode of operation of the system in FIG. 3, the signal generator 17 sequentially feeds test signals to the loudspeakers 1, 2, and 3 via the amplifiers 6, 7, and 8. The signal generator 17 gives the signal processor 18 information about the moments of the transmission (feed) of the test signals. The loudspeakers 1, 2, and 3 convert the test signals into corresponding sounds. The sounds propagate from the loudspeakers 1, 2, and 3 to the loudspeakers 4 and 5. The loudspeakers 4 and 5 convert the applied sounds into corresponding electric signals referred to as detected test signals. The detected test signals are sent from the loudspeakers 4 and 5 to the signal processor 18. The signal processor 18 measures the moments of the reception of the detected test signals. The signal processor 18 calculates the time intervals between the moments of the transmission of the test signals and the moments of the reception of the detected test signals. The signal processor 18 computes the distances among the loudspeakers 1-5 from the calculated time intervals, and detects the configuration or placement of the loudspeakers 1-5 in response to the computed distances. Then, the signal generator 17 sequentially feeds pulse-sound signals and sweep signals to the loudspeakers 1, 2, and 3 via the amplifiers 6, 7, and 8. The signal generator 17 gives the signal processor 18 information about the moments of the transmission (feed) of the pulse-sound signals and the sweep signals, and information about the waveforms and frequency spectrums thereof. The loudspeakers 1, 2, and 3 convert the pulse-sound signals and the sweep signals into corresponding sounds. The sounds propagate from the loudspeakers 1, 2, and 3 to the loudspeakers 4 and 5. The loudspeakers 4 and 5 convert the applied sounds into corresponding electric signals referred to as detected pulse-sound and sweep signals. The detected pulse-sound and sweep signals are sent from the loudspeakers 4 and 5 to the signal processor 18. The signal processor 18 analyzes the detected pulse-sound and sweep signals while using the information given by the signal generator 17. The signal processor 18 detects, from the results of the analyzation, the reverberation and frequency characteristics of a room where the loudspeakers 1-5 are located. The signal processor 18 sets the gains and frequency characteristics of the amplifiers 6-10 and the signal delay times provided by the amplifiers 6-10 in response to the detected configuration of the loudspeakers 1-5 and the detected reverberation and frequency characteristics of the room.

A normal reproducing mode of operation of the system in FIG. 3 follows the adjustment mode of operation thereof. During the normal reproducing mode of operation, the multi-channel sound source 16 outputs audio signals of the five channels to the amplifiers 6-10 respectively. The amplifiers 6-10 process and enlarge the audio signals into amplification-resultant signals in accordance with parameters including the gains and frequency characteristics and the signal delay times which have been set in the adjustment mode of operation. The amplifiers 6-10 feeds the amplification-resultant signals to the loudspeakers 1-5. The loudspeakers 1-5 convert the amplification-resultant signals into corresponding sounds.

The fourth known method does not consider the position of a listener relative to the loudspeakers 1-5. The conditions of the audio reproducing system which provide the sound field optimal for the listener depend on the position of the listener relative to the loudspeakers 1-5. Therefore, the generated sound field can be optimized only when the listener is in a specified correct point relative to the loudspeakers 1-5. The generated sound field is no longer optimal for the listener when the listener is distant from the specified correct point. Accordingly, it is difficult to generate the sound field optimal for the listener independent of the position of the listener relative to the loudspeakers 1-5.

In the fourth known method, the test signals are sequentially fed to the loudspeakers 1, 2, and 3. Thus, the detected test signals sequentially occur. The signal processor 18 sequentially implements the processing of the first detected test signal to compute the related inter-loudspeaker distances, the processing of the second detected test signal to compute the related inter-loudspeaker distances, and the processing of the third detected test signal to compute the related inter-loudspeaker distances. Similarly, the signal processor 18 sequentially analyzes the detected pulse-sound and sweep signals. Accordingly, the signal processor 18 is required to execute complicated computing and analyzing procedures causing a relatively great load.

### First embodiment

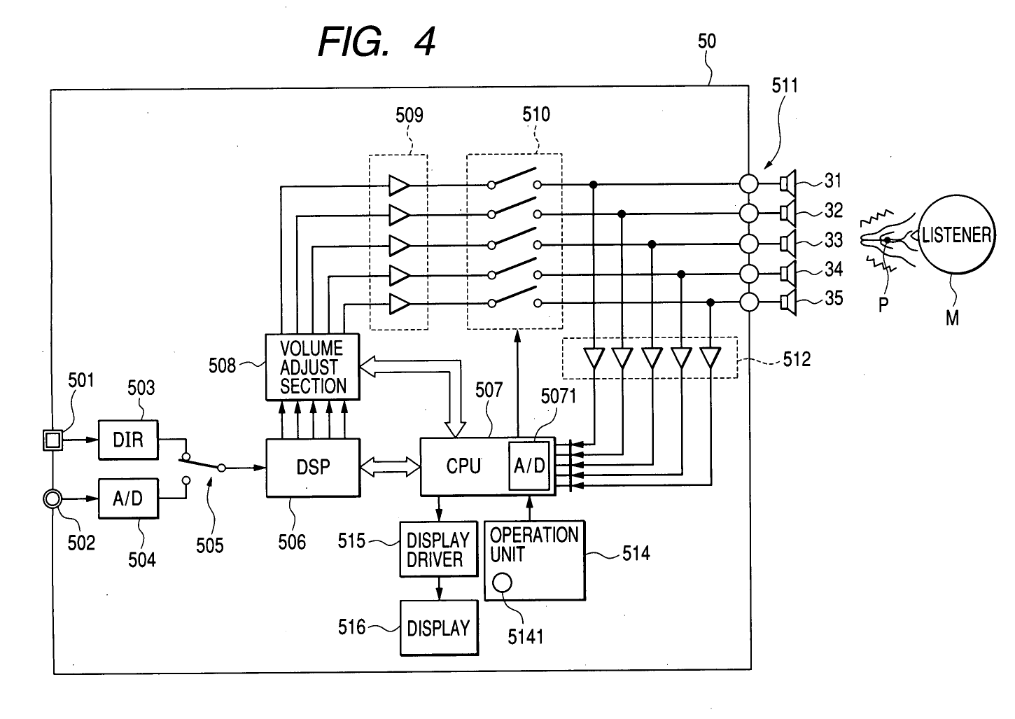

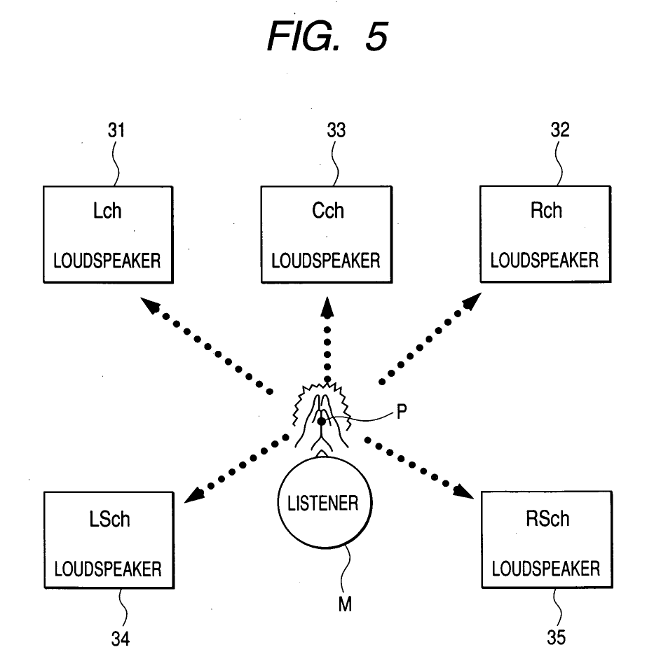

FIG. 4 shows an audio reproducing system according to a first embodiment of this invention. The system of FIG. 4 includes loudspeakers 31, 32, 33, 34, and 35, and a main apparatus 50 referred to as an audio reproducing apparatus 50. The loudspeakers 31-35 are connected with the audio reproducing apparatus 50. The loudspeakers 31, 32, 33, 34, and 35 are assigned to five channels, respectively. The five channels are a left channel Lch, a right channel Rch, a center channel Cch, a left surround channel LSch, and a right surround channel RSch. The loudspeakers 31-35 are arranged as shown in FIG. 5. The positions of the loudspeakers 31-35 may be changed.

As shown in FIG. 4, the audio reproducing apparatus 50 includes an input terminal 501 for a digital signal, an input terminal 502 for an analog signal, a digital interface receiver (DIR) 503, an analog-to-digital (A/D) converter 504, a switch 505, a digital signal processor (DSP) 506, a central processing unit (CPU) 507, a volume adjustment section (a gain adjustment section) 508, amplifiers 509, a relay 510, output terminals 511, amplifiers 512, an operation unit 514, a display driver 515, and a display 516.

The input terminal 501 is connected with the digital interface receiver 503. The input terminal 502 is connected with the A/D converter 504. The switch 505 is connected among the digital interface receiver 503, the A/D converter 504, and the DSP 506. The DSP 506 is connected with the CPU 507 and the volume adjustment section 508. The CPU 507 is connected with the volume adjustment section 508, the relay 510, and the operation unit 514. The CPU 507 is connected via the display driver 515 with the display 516. The volume adjustment section 508 is followed by the amplifiers 509. The amplifiers 509 are assigned to the five channels, respectively. The amplifiers 509 are connected with the output terminals 511 via switches of the relay 510, respectively. The output terminals 511 lead to the loudspeakers 31, 32, 33, 34, and 35, respectively. The output terminals 511 are connected with the CPU 507 via the amplifiers 512. The amplifiers 512 are assigned to the five channels, respectively.

The audio reproducing apparatus 50 can operate in a mode selected from different ones including a normal reproducing mode and a sound-field setting mode.

During the normal reproducing mode of operation, an input audio signal to be converted into corresponding sounds is fed to the audio reproducing apparatus 50. The input audio signal is a 2-channel signal containing audio information of the five channels, that is, the left channel Lch, the right channel Rch, the center channel Cch, the left surround channel LSch, and the right surround channel RSch. The input audio signal is of either a digital type or an analog type.

The digital input audio signal is fed via the input terminal 501 to the digital interface receiver 503. The digital interface receiver 503 generates a digital audio signal and various clock signals from the digital input audio signal. The digital interface receiver 503 outputs the digital audio signal to the switch 505.

The analog input audio signal is fed via the input terminal 502 to the A/D converter 504. The A/D converter 504 changes the analog input audio signal into a corresponding digital audio signal. The A/D converter 504 outputs the digital audio signal to the switch 505.

The switch 505 selects either the digital audio signal outputted from the digital interface receiver 503 or the digital audio signal outputted from the A/D converter 504, and passes the selected digital audio signal to the DSP 506. The switch 505 is changed depending on whether the input audio signal is of the digital type or the analog type.

The DSP 506 includes a combination of an input port, an output port, a processing section, a ROM, and a RAM. The output port includes digital-to-analog (D/A) converters assigned to the five channels respectively. The DSP 506 operates in accordance with a control program (a computer program) stored in the ROM. The control program is designed to enable the DSP 506 to implement the following operation steps. The DSP 506 receives the digital audio signal from the switch 505. The DSP 506 subjects the received digital audio signal to various processes to get digital audio signals of the five channels (the left channel Lch, the right channel Rch, the center channel Cch, the left surround channel LSch, and the right surround channel RSch). The processes include a process of deferring the digital audio signals of the five channels by adjustable delay times respectively. The D/A converters in the output port within the DSP 506 convert the digital audio signals into corresponding analog audio signals of the five channels. The DSP 506 outputs the analog audio signals to the volume adjustment section 508.

The input terminal 502 for an analog signal has two sub terminals assigned to the two channels, that is, the left channel Lch and the right channel Rch, respectively. The input terminal 502, the A/D converter 504, and the switch 505 may be omitted from the audio reproducing apparatus 50. In this case, the digital interface receiver 503 is directly connected with the DSP 506.

The volume adjustment section 508 adjusts the volumes or gains with respect to the audio signals of the five channels which are outputted from the DSP 506 to get volume-adjusted audio signals of the five channels. For example, the volume adjustment section 508 includes amplifiers having adjustable gains and assigned to the audio signals of the five channels respectively. The volume adjustment section 508 outputs the volume-adjusted audio signals to the amplifiers 509 respectively. The amplifiers 509 enlarge the volume-adjusted audio signals to get amplification-resultant audio signals of the five channels respectively. The amplification-resultant audio signals are fed from the amplifiers 509 to the loudspeakers 31, 32, 33, 34, and 35 via the switches of the relay 510 and the output terminals 511, respectively. The loudspeakers 31, 32, 33, 34, and 35 convert the amplification-resultant audio signals into corresponding sounds.

The operation unit 514 has a sound-field setting button 5141. The CPU 507 includes a combination of an input port, an output port, a processing section, a ROM, a RAM, and a nonvolatile memory. The input port includes A/D converters 5071 assigned to the five channels respectively. The CPU 507 operates in accordance with a control program (a computer program) stored in the ROM. The control program is designed to enable the CPU 507 to implement operation steps indicated hereafter.

When a listener M depresses the sound-field setting button 5141, the operation unit 514 sends the CPU 507 information representing the depression of the button 5141. The CPU 507 changes the operation of the audio reproducing apparatus 50 to the sound-field setting mode in response to the information of the button depression. Specifically, the CPU 507 controls the relay 510 in response to the information of the button depression so that the switches of the relay 510 will disconnect the amplifiers 509 from the output terminals 511. As a result, the feed of the amplification-resultant audio signals from the amplifiers 509 to the loudspeakers 31-35 is interrupted or inhibited. During the sound-field setting mode of operation, the loudspeakers 31-35 are used as microphones assigned to the five channels respectively. It is well-known that general loudspeakers can serve as microphones.

The operation unit 514 may be a combination of a remote-control transmitter and a related receiver. In this case, the sound-field setting button 5141 is provided on the remote-control transmitter.

During the sound-field setting mode of operation, the listener M claps his or her hands at a desired listening point P to generate a pulse-like test sound. The desired listening point P can be arbitrarily changed by the listener M. The test sound propagates from the desired listening point P to the loudspeakers 31-35. The loudspeakers 31-35 convert the applied test sound into corresponding electric signals referred to as test-sound signals of the five channels, respectively. The test-sound signals are sent from the loudspeakers 31-35 to the amplifiers 512, respectively. The amplifiers 512 enlarge the test-sound signals at a gain of, for example, about 70 dB to get amplification-resultant test-sound signals of the five channels. The amplifiers 512 output the amplification-resultant test-sound signals to the A/D converters 5071 within the CPU 507. The A/D converters 5071 change the amplification-resultant test-sound signals into corresponding digital test-sound signals of the five channels, respectively. For example, each of the A/D converters 5071 repetitively samples the related amplification-resultant test-sound signal at a period of, for example, 200 μs to get an analog signal sample, and converts the analog signal sample into a corresponding digital signal sample forming a time segment of the related digital test-sound signal.

During the sound-field setting mode of operation, the CPU 507 detects the moments of the arrival of the test sound at the respective loudspeakers 31-35 in response to the digital test-sound signals. The CPU 507 computes desired delay times of the five channels from the detected moments of the arrival of the test sound. Preferably, the desired delay times are chosen to compensate for the differences among the detected moments of the arrival of the test sound. This choice makes it possible that same-timing sounds of the five channels which are generated by the loudspeakers 31-35 reach the desired listening point P at substantially the same moment during the normal reproducing mode of operation. Furthermore, the CPU 507 detects the amplitudes (the volume levels or sound pressures) of the test sound applied to the loudspeakers 31-35 in response to the digital test-sound signals respectively. The CPU 507 computes desired gains for the five channels from the detected test-sound amplitudes. Preferably, the desired gains are chosen to compensate for the differences among the detected test-sound amplitudes. This choice makes it possible that at the desired listening point P, the amplitudes (the volumes) of sounds of the five channels which are generated by the loudspeakers 31-35 are balanced well during the normal reproducing mode of operation. Then, the CPU 507 controls the relay 510 so that the switches of the relay 510 will connect the amplifiers 509 to the output terminals 511. As a result, the sound-field setting mode of operation terminates.

The normal reproducing mode of operation follows the sound-field setting mode of operation. During the normal reproducing mode of operation, the CPU 507 controls the DSP 506 and sets the desired delay times therein. In addition, the CPU 507 controls the volume adjustment section 508 and sets the desired gains therein. Specifically, during the normal reproducing mode of operation, the input audio signals are transmitted to the loudspeakers 31-35 of the five channels respectively through the DSP 506, the volume adjustment section 508, the amplifiers 509, and the relay 510. The DSP 506 defers the digital audio signals of the five channels by the desired delay times respectively which are set by the CPU 507. As a result, same-timing sounds of the five channels which are generated by the loudspeakers 31-35 reach the desired listening point P at substantially the same moment. During the normal reproducing mode of operation, the volume adjustment section 508 adjusts the volumes or gains for the audio signals of the five channels in accordance with the desired gains which are set by the CPU 507. Therefore, at the desired listening point P, the amplitudes (the volumes) of sounds of the five channels which are generated by the loudspeakers 31-35 are balanced well.

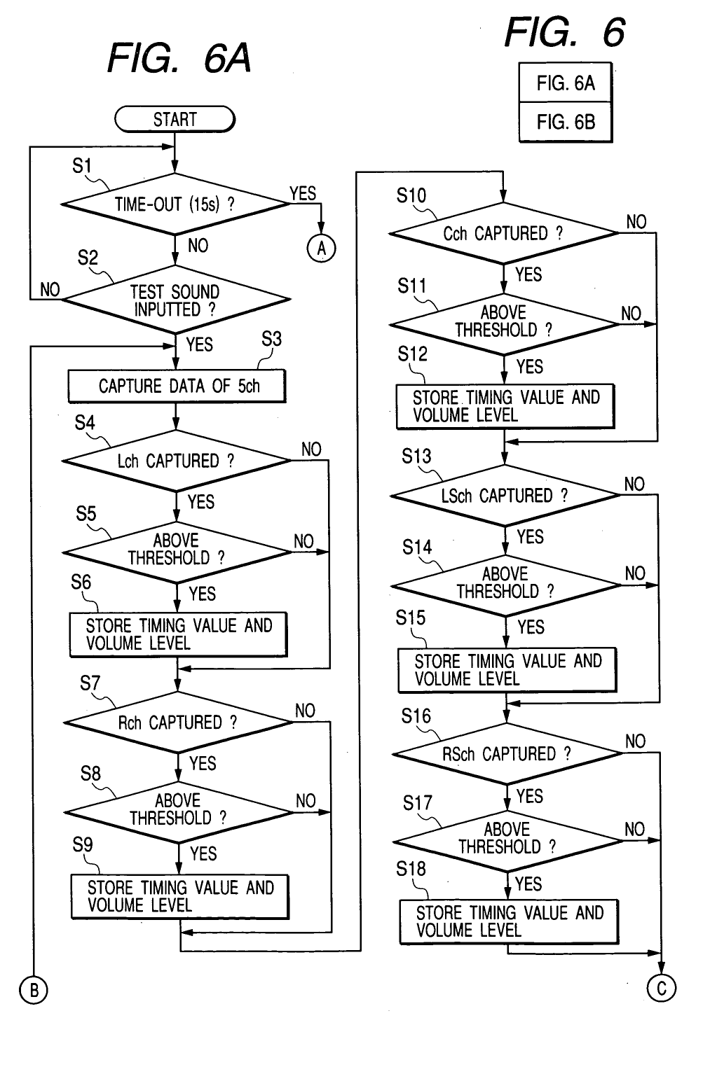

The control program for the CPU 507 includes a sound-field setting program which is started after the CPU 507 controls the relay 510 and thereby disconnects the amplifiers 509 from the output terminals 511 in response to the depression of the sound-field setting button 5141. FIGS. 6A and 6B are a flowchart of the sound-field setting program.

As shown in FIGS. 6A and 6B, a first step S1 of the program checks whether or not a time-out occurs, that is, whether or not a prescribed time (for example, 15 seconds) has elapsed. When the time-out occurs, that is, when the prescribed time has elapsed, the program advances from the step to a step S32. Otherwise, the program advances from the step S1 to a step S2.

The step S2 decides whether or not a pulse-like test sound is generated by referring to the output signals from the amplifiers 512. Specifically, the step S2 decides that a pulse-like test sound is generated when at least one of the output signals from the amplifiers 512 moves out of a substantially soundless state (a substantially zero-level state). The step S2 decides that a pulse-like test sound is not generated when all the output signals from the amplifiers 512 are in the substantially soundless states. When it is decided that a pulse-like test sound is generated, the program advances from the step S2 to a step S3. Otherwise, the program returns from the step S2 to the step S1.

Thus, in the case where a pulse-like test sound is generated by the listener M during the prescribed time (for example, 15 seconds), the program advances to the step S3. Otherwise, the program advances to the step S32.

The step S32 controls the display driver 515 so that the display 516 will indicate a message of “SILENT-ALL”. After the step S32, the current execution cycle of the program ends.

After the step S32, the program may return to the step S1 to make a retry or re-measurement for setting a sound filed. The maximum number of times of the re-measurement may be arbitrarily chosen.

The step S3 captures the current digital test-sound signals of the five channels.

A step S4 following the step S3 checks whether or not the current digital test-sound signal of the left channel Lch has been captured. When the current digital test-sound signal of the left channel Lch has been captured, the program advances from the step S4 to a step S5. Otherwise, the program jumps from the step S4 to a step S7.

The step S5 decides whether or not the volume level (the amplitude level) represented by the current digital test-sound signal of the left channel Lch exceeds a prescribed threshold level. When the volume level exceeds the prescribed threshold level, the program advances from the step S5 to a step S6. Otherwise, the program jumps from the step S5 to the step S7.

The step S6 stores information of the present moment (the present-timing value) into the RAM within the CPU 507 as an indication of the moment or timing of the arrival of the test sound at the loudspeaker 31 of the left channel Lch. In addition, the step S6 stores information of the volume level represented by the current digital test-sound signal of the left channel Lch into the RAM within the CPU 507. After the step S6, the program advances to the step S7.

The step S7 checks whether or not the current digital test-sound signal of the right channel Rch has been captured. When the current digital test-sound signal of the right channel Rch has been captured, the program advances from the step S7 to a step S8. Otherwise, the program jumps from the step S7 to a step S10.

The step S8 decides whether or not the volume level (the amplitude level) represented by the current digital test-sound signal of the right channel Rch exceeds the prescribed threshold level. When the volume level exceeds the prescribed threshold level, the program advances from the step S8 to a step S9. Otherwise, the program jumps from the step S8 to the step S10.

The step S9 stores information of the present moment (the present-timing value) into the RAM within the CPU 507 as an indication of the moment or timing of the arrival of the test sound at the loudspeaker 32 of the right channel Rch. In addition, the step S9 stores information of the volume level represented by the current digital test-sound signal of the right channel Rch into the RAM within the CPU 507. After the step S9, the program advances to the step S10.

The step S10 checks whether or not the current digital test-sound signal of the center channel Cch has been captured. When the current digital test-sound signal of the center channel Cch has been captured, the program advances from the step S10 to a step S11. Otherwise, the program jumps from the step S10 to a step S13.

The step S11 decides whether or not the volume level (the amplitude level) represented by the current digital test-sound signal of the center channel Cch exceeds the prescribed threshold level. When the volume level exceeds the prescribed threshold level, the program advances from the step S11 to a step S12. Otherwise, the program jumps from the step S11 to the step S13.

The step S12 stores information of the present moment (the present-timing value) into the RAM within the CPU 507 as an indication of the moment or timing of the arrival of the test sound at the loudspeaker 33 of the center channel Cch. In addition, the step S12 stores information of the volume level represented by the current digital test-sound signal of the center channel Cch into the RAM within the CPU 507. After the step S12, the program advances to the step S13.

The step S13 checks whether or not the current digital test-sound signal of the left surround channel LSch has been captured. When the current digital test-sound signal of the left surround channel LSch has been captured, the program advances from the step S13 to a step S14. Otherwise, the program jumps from the step S13 to a step S16.

The step S14 decides whether or not the volume level (the amplitude level) represented by the current digital test-sound signal of the left surround channel LSch exceeds the prescribed threshold level. When the volume level exceeds the prescribed threshold level, the program advances from the step S14 to a step S15. Otherwise, the program jumps from the step S14 to the step S16.

The step S15 stores information of the present moment (the present-timing value) into the RAM within the CPU 507 as an indication of the moment or timing of the arrival of the test sound at the loudspeaker 34 of the left surround channel LSch. In addition, the step S15 stores information of the volume level represented by the current digital test-sound signal of the left surround channel LSch into the RAM within the CPU 507. After the step S15, the program advances to the step S16.

The step S16 checks whether or not the current digital test-sound signal of the right surround channel RSch has been captured. When the current digital test-sound signal of the right surround channel RSch has been captured, the program advances from the step S16 to a step S17. Otherwise, the program jumps from the step S16 to a step S19.

The step S17 decides whether or not the volume level (the amplitude level) represented by the current digital test-sound signal of the right surround channel RSch exceeds the prescribed threshold level. When the volume level exceeds the prescribed threshold level, the program advances from the step S17 to a step S18. Otherwise, the program jumps from the step S17 to the step S19.

The step S18 stores information of the present moment (the present-timing value) into the RAM within the CPU 507 as an indication of the moment or timing of the arrival of the test sound at the loudspeaker 35 of the right surround channel RSch. In addition, the step S18 stores information of the volume level represented by the current digital test-sound signal of the right surround channel RSch into the RAM within the CPU 507. After the step S18, the program advances to the step S19.

The earliest one of the arrival timings (the arrival moments) detected by the steps S6, S9, S12, S15, and S18 is set to a timing value of 0 (0 ms). The other arrival timings are set to timing values measured from 0 (0 ms).

The step S19 decides whether or not the timing-value information and the volume-level information about all the five channels have been stored by the steps S6, S9, S12, S15, and S18. When the timing-value information and the volume-level information about all the five channels have been stored, the program advances from the step S19 to a step S20. Otherwise, the program advances from the step S19 to a step S25.

The listener (the user) M can connect only selected ones of the loudspeakers 31-35 to the audio reproducing apparatus 50. In this case, the step S19 decides whether or not the timing-value information and the volume-level information about only the connected-loudspeaker channels have been stored.

The steps S6, S9, S12, S15, and S18 may be modified to implement the following procedure. Each of the steps S6, S9, S12, S15, and S18 stores, into the RAM within the CPU 507, information of the maximum of the volume levels represented by plural samples of the digital test-sound signal of the related channel. Alternatively, each of the steps S6, S9, S12, S15, and S18 stores, into the RAM within the CPU 507, information of the mean or average among the volume levels represented by plural samples of the digital test-sound signal of the related channel.

The step S20 reads out the timing-value information and the volume-level information from the RAM within the CPU 507. The step S20 retrieves the timing values and the volume levels of the five channels from the read-out information. On the basis of the retrieved timing values and volume levels, the step S20 generates data for setting (adjusting) timings at which respective sounds generated by the loudspeakers 31-35 of the five channels reach the desired listening point P, and data for setting (adjusting) the volumes at which the listener M in the desired listening point P listens to the respective sounds of the five channels.

The step S20 will be further explained below. Preferably, same-timing sounds of the five channels which are generated by the loudspeakers 31-35 reach the desired listening point P at substantially the same moment during the normal reproducing mode of operation. The differences among the timing values of the five channels which are computed in the sound-field setting mode of operation are equivalent to estimated differences among the moments at which same-timing sounds of the five channels reach the desired listening point P from the loudspeakers 31-35 during the normal reproducing mode of operation. The step S20 generates timing-related data for nullifying the estimated differences among the moments at which same-timing sounds of the five channels reach the desired listening point P from the loudspeakers 31-35. The step S20 uses the generated timing-related data as the delay-time setting data. As understood from the above explanation, the delay-time setting data are designed to nullify the estimated differences among the moments at which same-timing sounds of the five channels reach the desired listening point P from the loudspeakers 31-35. The delay-timing setting data represent desired delay times for audio signals to be converted into corresponding sounds by the loudspeakers 31-35 respectively.

Preferably, at the desired listening point P, the amplitudes (the volumes) of sounds of the five channels which are generated by the loudspeakers 31-35 are balanced well during the normal reproducing mode of operation. The differences among the volume levels of the five channels which are computed in the sound-field setting mode of operation are equivalent to estimated differences among the volumes at which the listener M in the desired listening point P listens to same-level sounds coming from the loudspeakers 31-35 of the five channels during the normal reproducing mode of operation. The step S20 generates volume-related data for nullifying the estimated differences among the volumes at which the listener M in the desired listening point P listens to same-level sounds coming from the loudspeakers 31-35 of the five channels. The step S20 uses the generated volume-related data as the volume adjusting data. The volume adjusting data represent desired volumes or gains for audio signals to be converted into corresponding sounds by the loudspeakers 31-35 respectively.

In more detail, the step S20 compares the volume levels of the five channels which are computed in the sound-field setting mode of operation. As a result of the comparison, the step S20 detects the differences among the volume levels of the five channels. On the basis of the comparison result and the detected differences, the step S20 generates the volume adjusting data for nullifying the estimated differences among the volumes at which the listener M in the desired listening point P listens to same-level sounds coming from the loudspeakers 31-35 of the five channels.

During the normal reproducing mode of operation which follows the sound-field setting mode of operation, the CPU 507 sets the delay times for the digital audio signals of the five channels in the DSP 506 in accordance with the delay-time setting data. Specifically, the CPU 507 equalizes the delay times for the digital audio signals to the desired delay times represented by the delay-time setting data. In addition, the CPU 507 sets the volumes or gains for the audio signals of the five channels in the volume adjustment section 508 in accordance with the volume adjusting data. Specifically, the CPU 507 equalizes the volumes or gains for the audio signals to the desired volumes or gains represented by the volume adjusting data.

The step S20 may implement the following procedure. The step S20 calculates the mean between the timing value of the left channel Lch and the timing value of the right channel Rch. The step S20 uses the calculated mean as a reference timing value. In addition, the step S20 calculates the mean between the volume level of the left channel Lch and the volume level of the right channel Rch. The step S20 uses the calculated mean as a reference volume level. The step S20 computes the difference Δt (Cch) of the timing value of the center channel Cch from the reference timing value, the difference Δt (LSch) of the timing value of the left surround channel LSch from the reference timing value, and the difference Δt (RSch) of the timing value of the right surround channel RSch from the reference timing value. In addition, the step S20 computes the difference of the volume level of the center channel Cch from the reference volume level, the difference of the volume level of the left surround channel LSch from the reference volume level, and the difference of the volume level of the right surround channel from the reference volume level.

In response to the computed timing difference Δt (Cch), the step S20 generates delay-time setting data for enabling same-timing sounds generated by the loudspeakers 31, 32, and 33 of the left channel Lch, the right channel Rch, and the center channel Cch to reach the desired listening point P at substantially the same moment during the normal reproducing mode of operation.

It is assumed that the time values of the center channel Cch, the left channel Lch, and the right channel Rch are equal to 0 ms, 1 ms, and 2 ms, respectively. In this case, the mean between the timing value of the left channel Lch and the timing value of the right channel Rch is equal to 1.5 ms. Accordingly, the step S20 generates delay-time setting data for providing a delay time of 1.5 ms to the digital audio signal of the center channel Cch.

Then, in response to the computed timing differences Δt (LSch) and Δt (RSch), the step S20 generates delay-time setting data for enabling same-timing sounds generated by the loudspeakers 31-35 of the five channels to reach the desired listening point P at substantially the same moment during the normal reproducing mode of operation. In this case, the step S20 may generate delay-time setting data for enabling only same-timing sounds generated by the loudspeakers 34 and 35 of the left and right surround channels LSch and RSch to reach the desired listening point P at substantially the same moment during the normal reproducing mode of operation.

Subsequently, the step S20 generates, in response to the computed volume differences, volume adjusting data for substantially equalizing the volumes at which the listener M in the desired listening point P listens to same-level sounds coming from the loudspeakers 31-35 of the five channels during the normal reproducing mode of operation.

The generation of the volume adjusting data may precede the generation of the delay-time setting data. The generation of the volume adjusting data may mix with the generation of the delay-time setting data in time domain.

A step S21 following the step S20 computes the difference between the time value of the left channel Lch and the time value of the right channel Rch. The step S21 calculates the absolute value of the computed difference. The step S21 decides whether or not the calculated absolute value is greater than a first prescribed value equal to, for example, 5 ms. When the calculated absolute value is greater than the first prescribed value, the program advances from the step S21 to a step S24. Otherwise, the program advances from the step S21 to a step S22.

The step S22 computes the difference between the time value of the left surround channel LSch and the time value of the right surround channel RSch. The step S22 calculates the absolute value of the computed difference. The step S22 decides whether or not the calculated absolute value is greater than a second prescribed value equal to, for example, 10 ms. When the calculated absolute value is greater than the second prescribed value, the program advances from the step S22 to the step S24. Otherwise, the program advances from the step S22 to a step S23.

The step S23 controls the display driver 515 so that the display 516 will indicate a message of “OK”. The step S23 saves the delay-time setting data and the volume adjusting data in the nonvolatile memory or the RAM within the CPU 507 for later use in the normal reproducing mode of operation. After the step S23, the current execution cycle of the program ends.

The step S24 controls the display driver 515 so that the display 516 will indicate a message of “FAILED”. The step S24 discards the delay-time setting data and the volume adjusting data. After the step S24, the current execution cycle of the program ends.

The absolute value of the difference between the time value of the left channel Lch and the time value of the right channel Rch which is greater than 5 ms means that the difference in distance to the desired listening point P between the loudspeaker 31 of the left channel Lch and the loudspeaker 32 of the right channel Rch is longer than 1.5 m. In the case where the absolute value of the difference between the time value of the left channel Lch and the time value of the right channel Rch which is greater than 5 ms, the step S21 acts to inhibit the setting of a sound filed.

The step S25 decides whether or not a preset time interval has elapsed since the moment of the first execution of the step S3. The preset time interval is equal to 30 ms. When the preset time interval has elapsed, the program advances from the step S25 to a step S26. Otherwise, the program returns to the step S3.

In the case where the test sound has not yet reached one of the loudspeakers 31-35 at least 30 ms after the arrival of the test sound at another of the loudspeakers 31-35, there is a 9-meter difference or more in distance to the desired listening point P between the two of the loudspeakers 31-35. In this case, the step S25 acts to inhibit the setting of a sound field.

The step S26 decides whether or not the test sound has reached both the loudspeakers 31 and 32 by referring to the time values of the left and right channels Lch and Rch. When the test sound has reached both the loudspeakers 31 and 32, the program advances from the step S26 to a step S27. Otherwise, the program advances from the step S26 to a step S31.

The step S27 computes the difference between the time value of the left channel Lch and the time value of the right channel Rch. The step S27 calculates the absolute value of the computed difference. The step S27 decides whether or not the calculated absolute value is greater than the first prescribed value (equal to, for example, 5 ms). When the calculated absolute value is greater than the first prescribed value, the program advances from the step S27 to the step S31. Otherwise, the program advances from the step S27 to a step S28.

The step S28 decides whether or not the test sound has reached both the loudspeakers 34 and 35 by referring to the time values of the left and right surround channels LSch and RSch. When the test sound has reached both the loudspeakers 34 and 35, the program advances from the step S28 to a step S29. Otherwise, the program advances from the step S28 to the step S31.

The step S29 computes the difference between the time value of the left surround channel LSch and the time value of the right surround channel RSch. The step S29 calculates the absolute value of the computed difference. The step S29 decides whether or not the calculated absolute value is greater than the second prescribed value (equal to, for example, 10 ms). When the calculated absolute value is greater than the second prescribed value, the program advances from the step S29 to the step S31. Otherwise, the program advances from the step S29 to a step S30.

The step S30 controls the display driver 515 so that the display 516 will indicate a message of “SILENT”. After the step S30, the current execution cycle of the program ends.

The step S31 controls the display driver 515 so that the display 516 will indicate a message of “FAILED”. After the step S31, the current execution cycle of the program ends.

After the execution of the step S23, the CPU 507 controls the relay 510 and thereby connects the amplifiers 509 to the output terminals 511. As a result, the sound-field setting mode of operation terminates.

The normal reproducing mode of operation follows the sound-field setting mode of operation. During the normal reproducing mode of operation, the input audio signals are transmitted to the loudspeakers 31-35 of the five channels respectively through the DSP 506, the volume adjustment section 508, the amplifiers 509, and the relay 510. The CPU 507 retrieves the delay-time setting data and the volume adjusting data from the nonvolatile memory or the RAM. The CPU 507 controls the DSP 506 and sets the delay times of the five channels in accordance with the delay-time setting data. Specifically, the CPU 507 sets the delay times to the desired ones represented by the delay-time setting data. The DSP 506 defers the digital audio signals of the five channels by the delay times respectively which are set by the CPU 507. As a result, same-timing sounds of the five channels which are generated by the loudspeakers 31-35 reach the desired listening point P at substantially the same moment. Furthermore, the CPU 507 controls the volume adjustment section 508 and sets the gains of the five channels in accordance with the volume adjusting data. Specifically, the CPU 507 sets the gains to the desired ones represented by the volume adjusting data. The volume adjustment section 508 adjusts the volumes or gains for the audio signals of the five channels in accordance with the gains which are set by the CPU 507. Therefore, at the desired listening point P, the amplitudes (the volumes) of sounds of the five channels which are generated by the loudspeakers 31-35 are balanced well.

In the absence of the arrival of the test sound at one or more of the loudspeakers 31-35, the CPU 507 may decide that the loudspeaker or loudspeakers in question are not connected with the audio reproducing apparatus 50. In this case, the CPU 507 considers the non-connection in generating the delay-time setting data and the volume adjusting data for the channels corresponding to the other loudspeakers.

As understood from the above description, the setting of a sound field falls into a stand-by state when the listener M depresses the sound-field setting button 5141. Then, the setting of a sound field starts when the listener M generates a pulse-like test sound at the desired listening point P. It is sufficient for the listener M to perform the two steps, that is, the depression of the sound-field setting button 5141 and the generation of a pulse-like test sound.

The loudspeakers 31-35 are used as microphones for converting the applied test sound into corresponding electric signals of the five channels. The CPU 507 analyzes the electric signals. The CPU 507 automatically sets an optimal sound field at the desired listening point P in response to the results of the analyzation.

Thus, in order to set an optimal sound field, it is sufficient for the listener M to perform simple operation. The listener M can arbitrarily choose the desired listening point P. The listener M can have a feeling of participation in the setting of an optimal sound field. Therefore, the setting of an optimal sound field is enjoyable to the listener M.

Measurements were made as to the waveforms of electric signals generated by the loudspeakers 31 and 32 of the left and right channels Lch and Rch under first, second, and third conditions.

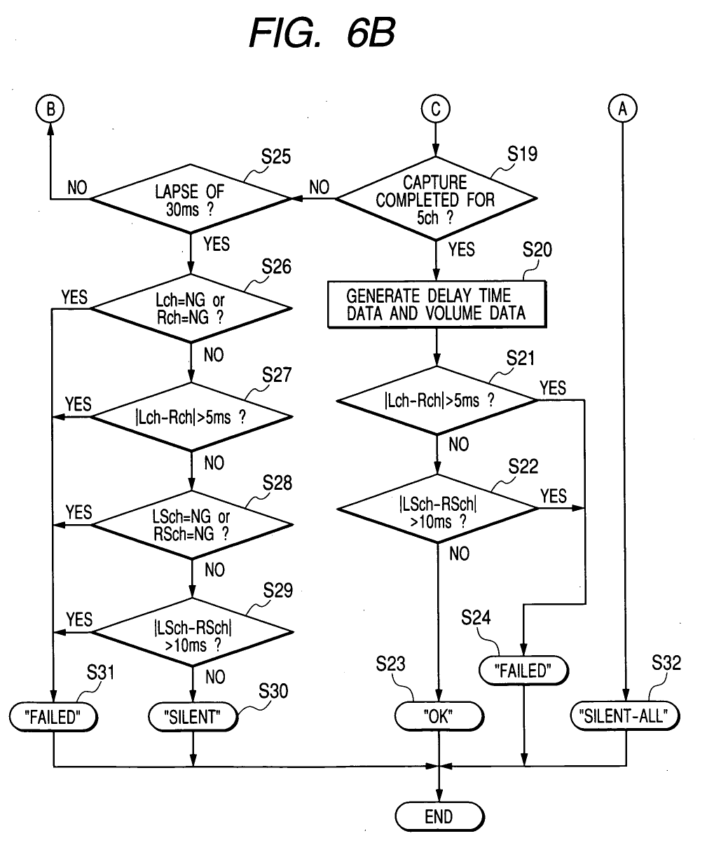

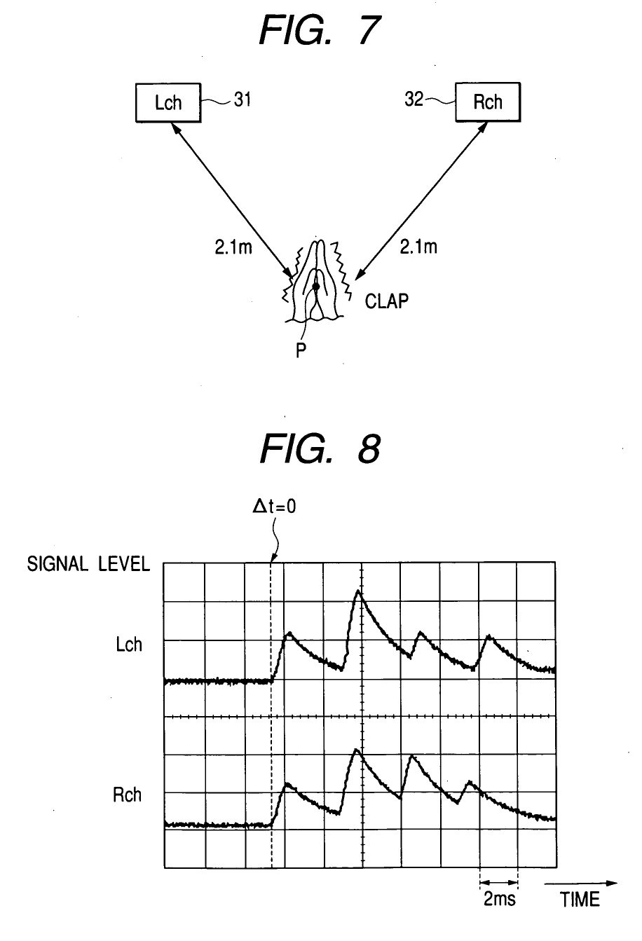

In the first condition, as shown in FIG. 7, both the loudspeakers 31 and 32 of the left and right channels Lch and Rch were 2.1-m distant from the desired listening point P. The listener M clapped his or her hands at the desired listening point P to generate a pulse-like test sound. The test sound was applied to the loudspeakers 31 and 32. In the first condition, as shown in FIG. 8, there was no timing difference between the electric signals (Lch and Rch) generated by the loudspeakers 31 and 32 which reflected the applied test sound.

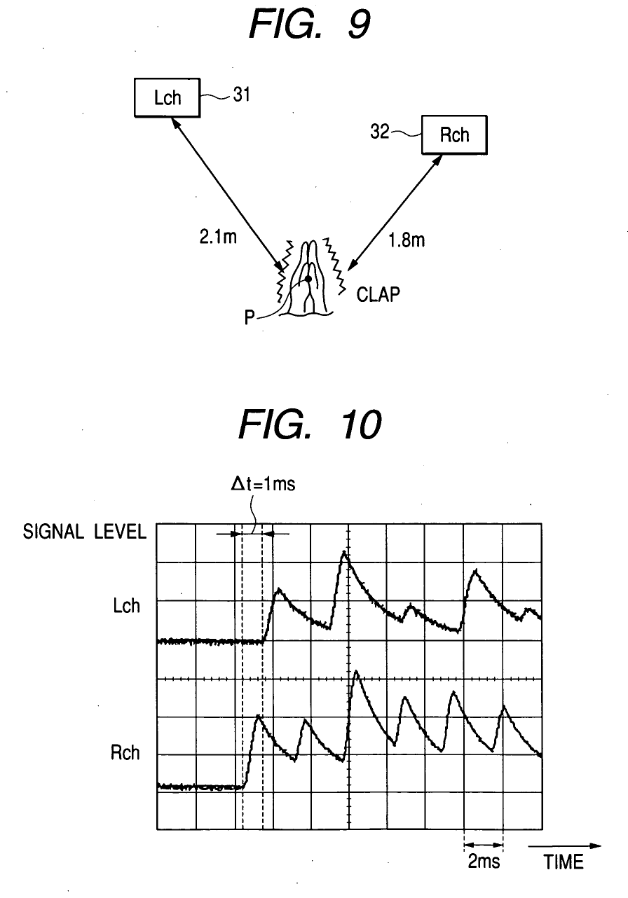

In the second condition, as shown in FIG. 9, the loudspeaker 31 of the left channel Lch was 2.1-m distant from the desired listening point P while the loudspeaker 32 of the right channel Rch was 1.8-m distant therefrom. The listener M clapped his or her hands at the desired listening point P to generate a pulse-like test sound. The test sound was applied to the loudspeakers 31 and 32. In the second condition, as shown in FIG. 10, there was a timing difference of 1 ms between the electric signals (Lch and Rch) generated by the loudspeakers 31 and 32 which reflected the applied test sound.

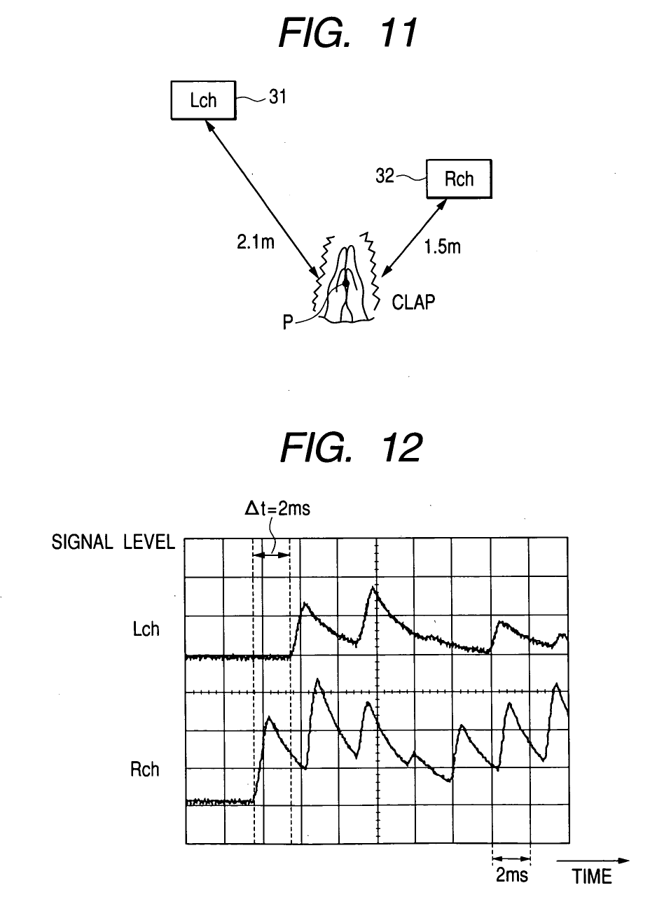

In the third condition, as shown in FIG. 11, the loudspeaker 31 of the left channel Lch was 2.1-m distant from the desired listening point P while the loudspeaker 32 of the right channel Rch was 1.5-m distant therefrom. The listener M clapped his or her hands at the desired listening point P to generate a pulse-like test sound. The test sound was applied to the loudspeakers 31 and 32. In the second condition, as shown in FIG. 12, there was a timing difference of 2 ms between the electric signals (Lch and Rch) generated by the loudspeakers 31 and 32 which reflected the applied test sound.

FIGS. 8, 10, and 12 reveal that the CPU 507 can accurately derive the timing difference between the arrivals of a pulse-like test sound at the loudspeakers 31 and 32 of the left and right channels Lch and Rch from the electric signals generated by the loudspeakers 31 and 32 during the sound-field setting mode of operation.

### Second Embodiment

A second embodiment of this invention is similar to the first embodiment thereof except for design changes mentioned hereafter.

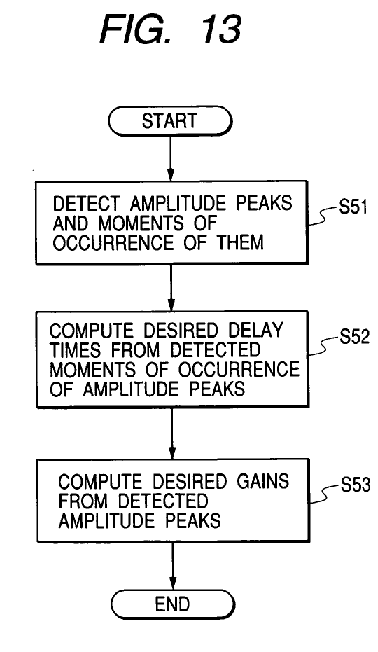

FIG. 13 is a flowchart of a sound-field setting program in the second embodiment of this invention. The sound-field setting program in FIG. 13 replaces that in FIGS. 6A and 6B.

As shown in FIG. 13, a first step S51 of the program detects the peaks of the amplitudes (the levels) represented by the digital test-sound signals of the five channels respectively. In addition, the step S51 detects the moments of the occurrence of the detected peaks. The detected peak-occurrence moments indicate the moments of the arrival of a pulse-like test sound at the loudspeakers 31-35 respectively. The pulse-like test sound is generated at the desired listening point P.

A step S52 following the step S51 computes desired delay times of the five channels from the detected moments of the occurrence of the detected peaks. Preferably, the desired delay times are chosen to compensate for the differences among the detected moments of the occurrence of the detected peaks. This choice makes it possible that same-timing sounds of the five channels which are generated by the loudspeakers 31-35 reach the desired listening point P at substantially the same moment during the normal reproducing mode of operation. The step S52 stores information of the desired delay times in the nonvolatile memory or the RAM within the CPU 507 for later use in the normal reproducing mode of operation.

A step S53 subsequent to the step S52 computes desired gains for the five channels from the detected peaks. Preferably, the desired gains are chosen to compensate for the differences among the detected peaks. This choice makes it possible that at the desired listening point P, the amplitudes (the volumes) of sounds of the five channels which are generated by the loudspeakers 31-35 are balanced well during the normal reproducing mode of operation. The step S53 stores information of the desired gains in the nonvolatile memory or the RAM within the CPU 507 for later use in the normal reproducing mode of operation. After the step S53, the current execution cycle of the program ends.

The normal reproducing mode of operation follows the termination of the execution of the sound-field setting program in FIG. 13. During the normal reproducing mode of operation, the CPU 507 retrieves the information of the desired delay times and the information of the desired gains from the nonvolatile memory or the RAM. The CPU 507 controls the DSP 506 and sets the desired delay times therein. In addition, the CPU 507 controls the volume adjustment section 508 and sets the desired gains therein. Specifically, during the normal reproducing mode of operation, the input audio signals are transmitted to the loudspeakers 31-35 of the five channels respectively through the DSP 506, the volume adjustment section 508, the amplifiers 509, and the relay 510. The DSP 506 defers the digital audio signals of the five channels by the desired delay times respectively which are set by the CPU 507. As a result, same-timing sounds of the five channels which are generated by the loudspeakers 31-35 reach the desired listening point P at substantially the same moment. During the normal reproducing mode of operation, the volume adjustment section 508 adjusts the volumes or gains for the audio signals of the five channels in accordance with the desired gains which are set by the CPU 507. Therefore, at the desired listening point P, the amplitudes (the volumes) of sounds of the five channels which are generated by the loudspeakers 31-35 are balanced well.

### Advantages Provided by the Invention

It is possible to accurately analyze timing-related conditions and volume-related conditions of plural channels which depend on the configuration or placement of loudspeakers and a listening point. Therefore, it is possible to properly set an optimal sound field in response to the results of the analyzation.

The present method of setting an optimal sound field is easier than the fully manual method and the prior-art method in Japanese patent application publication number 6-38300/1994.

It is unnecessary to use a microphone. Thus, it is possible to prevent a cost increase which would be caused by a microphone.

The setting of an optimal sound field is relatively simple. Therefore, in this regard, it is sufficient for the CPU 507 to bear a relatively small load.

What is claimed is:

1. A method of setting a sound field generated when audio signals of plural channels which are outputted from an audio signal reproducing apparatus are reproduced from loudspeakers of the respective channels, the method comprising the steps of:
cutting off the feed of the audio signals from the audio signal reproducing apparatus to the loudspeakers of the respective channels;
capturing a test sound generated by a listener at a listening point by the loudspeakers of the respective channels as sound pickup data;
detecting and comparing volume levels at predetermined points of the sound pickup data captured by the loudspeakers of the respective channels, and thereby generating volume adjusting data of the audio signals of the respective channels; and
controlling volumes of the audio signals of the respective channels in response to the volume adjusting data respectively.

2. A method of setting a sound field which is recited in claim 1, further comprising the steps of:
detecting and comparing timings of the data values at the predetermined points of the sound pickup data captured by the loudspeakers of the respective channels, and thereby generating delay time setting data of the audio signals of the respective channels; and
controlling delay times of the audio signals of the respective channels in response to the delay time setting data respectively.

3. A method of setting a sound field which is recited in claim 1, wherein the predetermined points are points of timings at which exceeding a prescribed threshold occurs.

4. A method of setting a sound field which is recited in claim 2, wherein the predetermined points are points of timings at which exceeding a prescribed threshold occurs.

5. A computer program for setting a sound field generated when audio signals of plural channels which are outputted from an audio signal reproducing apparatus are reproduced from loudspeakers of the respective channels, the computer program comprising the steps of:
cutting off the feed of the audio signals from the audio signal reproducing apparatus to the loudspeakers of the respective channels;
capturing a test sound generated by a listener at a listening point by the loudspeakers of the respective channels as sound pickup data;
detecting and comparing volume levels at predetermined points of the sound pickup data captured by the loudspeakers of the respective channels, and thereby generating volume adjusting data of the audio signals of the respective channels; and
controlling volumes of the audio signals of the respective channels in response to the volume adjusting data respectively.

6. A computer program for setting a sound field which is recited in claim 5, further comprising the steps of:
detecting and comparing timings of the data values at the predetermined points of the sound pickup data captured by the loudspeakers of the respective channels, and thereby generating delay time setting data of the audio signals of the respective channels; and
controlling delay times of the audio signals of the respective channels in response to the delay time setting data respectively.

7. A computer program for setting a sound field which is recited in claim 5, wherein the predetermined points are points of timings at which exceeding a prescribed threshold occurs.

8. A computer program for setting a sound field which is recited in claim 6, wherein the predetermined points are points of timings at which exceeding a prescribed threshold occurs.

9. An audio reproducing apparatus provided with a system for setting a sound field generated when audio signals of plural channels which are outputted from the audio reproducing apparatus are reproduced from loudspeakers of the respective channels, the audio reproducing apparatus comprising:
means for cutting off the feed of the audio signals from the audio signal reproducing apparatus to the loudspeakers of the respective channels;
means for capturing a test sound generated by a listener at a listening point by the loudspeakers of the respective channels as sound pickup data;
a detector for detecting volume levels at predetermined points of the sound pickup data captured by the loudspeakers of the respective channels;
a generator for comparing the detected volume levels, and thereby generating volume adjusting data of the audio signals of the respective channels; and
a controller for controlling volumes of the audio signals of the respective channels in response to the volume adjusting data respectively.

10. An audio reproducing apparatus as recited in claim 9, further comprising:
a detector for detecting timings of the data values at the predetermined points of the sound pickup data captured by the loudspeakers of the respective channels;
a generator for comparing the detected timings of the data values, and thereby generating delay time setting data of the audio signals of the respective channels; and
a controller for controlling delay times of the audio signals of the respective channels in response to the delay time setting data respectively.

11. An audio reproducing apparatus as recited in claim 9, wherein the predetermined points are points of timings at which exceeding a prescribed threshold occurs.

12. An audio reproducing apparatus as recited in claim 10, wherein the predetermined points are points of timings at which exceeding a prescribed threshold occurs.

13. A sound-field setting system comprising:
loudspeakers of plural channels;
means for cutting off the feed of the audio signals from the audio signal reproducing apparatus to the loudspeakers of the respective channels;
means for capturing a test sound generated by a listener at a listening point by the loudspeakers of the respective channels as sound pickup data;
a detector for detecting volume levels at predetermined points of the sound pickup data captured by the loudspeakers of the respective channels;
a generator for comparing the detected volume levels, and thereby generating volume adjusting data of the audio signals of the respective channels; and
a controller for controlling volumes of the audio signals of the respective channels in response to the volume adjusting data respectively.

14. A sound-field setting system as recited in claim 13, further comprising:
a detector for detecting timings of the data values at the predetermined points of the sound pickup data captured by the loudspeakers of the respective channels;
a generator for comparing the detected timings of the data values, and thereby generating delay time setting data of the audio signals of the respective channels; and
a controller for controlling delay times of the audio signals of the respective channels in response to the delay time setting data respectively.

15. A sound-field setting system as recited in claim 13, wherein the predetermined points are points of timings at which exceeding a prescribed threshold occurs.

16. A sound-field setting system as recited in claim 14, wherein the predetermined points are points of timings at which exceeding a prescribed threshold occurs.

17. A sound-field setting system comprising:
loudspeakers of plural channels;
first means for using the loudspeakers as microphones to convert a test sound generated at a desired listening point into corresponding electric signals respectively;
second means for detecting amplitudes of the electric signals generated by the loudspeakers;
third means for setting desired gains for input audio signals of the plural channels in response to the amplitudes detected by the second means;
fourth means for amplifying the input audio signals at the desired gains set by the third means to generate amplified audio signals respectively; and
fifth means for feeding the amplified audio signals generated by the fourth means to the loudspeakers respectively.

18. A sound-field setting system comprising:
loudspeakers of plural channels;
first means for using the loudspeakers as microphones to convert a test sound generated at a desired listening point into corresponding electric signals respectively;
second means for detecting moments of arrival of the test sound at the loudspeakers in response to the electric signals generated by the loudspeakers respectively;
third means for delaying input audio signals by delay times depending on the moments detected by the second means to generate delayed audio signals respectively; and
fourth means for feeding the delayed audio signals to the loudspeakers respectively.

19. A sound-field setting system comprising:
loudspeakers of plural channels;
first means for using the loudspeakers as microphones to convert a test sound generated at a desired listening point into corresponding electric signals respectively;
second means for detecting moments of arrival of the test sound at the loudspeakers in response to the electric signals generated by the loudspeakers respectively;
third means for setting desired delay times for input audio signals of the plural channels in response to the moments detected by the second means;
fourth means for delaying the input audio signals by the desired delay times set by the third means to generate delayed audio signals respectively; and
fifth means for feeding the delayed audio signals to the loudspeakers respectively.

20. A sound-field setting system as recited in claim 19, further comprising:
sixth means for detecting amplitudes of the electric signals generated by the loudspeakers;
seventh means for setting desired gains for the input audio signals in response to the amplitudes detected by the sixth means;
eighth means for amplifying the input audio signals at the desired gains set by the seventh means to generate amplified audio signals respectively; and
ninth means for feeding the amplified audio signals generated by the eighth means to the loudspeakers respectively.
